(19) United States
(12) Patent Application Publication
(10) Pub. No.: US 2023/0189426 A1
(43) Pub. Date: Jun. 15, 2023

(54) Integrated Attenuator with Thermal Vias

(71) Applicant: International Business Machines Corporation, Armonk, NY (US)

(72) Inventor: Young Kwark, Chappaqua, NY (US)

(21) Appl. No.: 17/644,431

(22) Filed: Dec. 15, 2021

(51) Int. Cl. H05K 1/02; H01P 1/22

(52) U.S. Cl. CPC H05K 1/0201; H01P 1/225

(57) ABSTRACT

An attenuator comprising a first thermal reservoir and a first metal layer located on top of the first thermal reservoir. A first dielectric layer located on top of the first metal layer and a resistor located on top the first dielectric layer. A second dielectric layer located on top of the resistor and a second metal layer located on top of the second dielectric layer. A second thermal reservoir located on top the third metal layer and wherein the resistor is split or perforated by a thermal shunt, wherein the thermal shunt includes a thermal column that directs the heat generated by the resistor vertically upwards or downwards into the first and second thermal reservoirs, respectively.

### STATEMENT REGARDING FEDERALLY SPONSORED RESEARCH OR DEVELOPMENT

This invention was made with U.S. Government support. The U.S. Government has certain rights in this invention.

### BACKGROUND

The present invention relates to attenuator, and more specifically, controlling the heat generated by the attenuator.

Coaxial attenuators are heat sunk to various temperature cryostat bulkhead plates. The coaxial attenuators are used to thermalize the noise power in the signal lines to avoid raising the noise floor in the qubit environment. Coaxial attenuators require large areas per connector and will severely limit the channel count that can be housed in the cryostat.

### BRIEF SUMMARY

Additional aspects and/or advantages will be set forth in part in the description which follows and, in part, will be apparent from the description, or may be learned by practice of the invention.

An attenuator comprising a first thermal reservoir and a first metal layer located on top of the first thermal reservoir. A first dielectric layer located on top of the first metal layer and a resistor located on top the first dielectric layer. A second dielectric layer located on top of the resistor and a second metal layer located on top of the second dielectric layer. A second thermal reservoir located on top the third metal layer and wherein the resistor is split or perforated by a thermal shunt, wherein the thermal shunt includes a thermal column that directs the heat generated by the resistor vertically upwards or downwards into the first and second thermal reservoirs, respectively.

An attenuator comprising a first thermal reservoir and a first metal layer located on top of the first thermal reservoir. A first dielectric layer located on top of the first metal layer and a resistor located on top the first dielectric layer. A second dielectric layer located on top of the resistor and a second metal layer located on top of the second dielectric layer. A second thermal reservoir located on top the third metal layer and a top thermal via that extends upwards from resistor through the second dielectric layer to the second thermal reservoir, wherein the top thermal via is filled with a thermal interface material. A bottom thermal via that extends downwards from the dividing metal plate through the first dielectric layer to the first thermal reservoir, wherein the bottom thermal via is filled with a thermal interface material.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 represents a cross sectional view depicting an attenuator, according to an example embodiment.

FIG. 2 represents a cross sectional view of a split resistor with the thermal vias, according to an example embodiment.

FIG. 3 represents a cross sectional view depicting an attenuator, according to an example embodiment.

FIG. 4 represents a cross sectional view of a split resistor with the thermal vias, according to an example embodiment.

FIG. 5 represents a cross sectional view depicting an attenuator, according to an example embodiment.

FIG. 6 represents a cross sectional view of a split resistor with the thermal vias, according to an example embodiment.

Elements of the figures are not necessarily to scale and are not intended to portray specific parameters of the invention. For clarity and ease of illustration, dimensions of elements may be exaggerated. The detailed description should be consulted for accurate dimensions. The drawings are intended to depict only typical embodiments of the invention, and therefore should not be considered as limiting the scope of the invention. In the drawings, like numbering represents like elements.

### DETAILED DESCRIPTION

Exemplary embodiments now will be described more fully herein with reference to the accompanying drawings, in which exemplary embodiments are shown. This disclosure may, however, be embodied in many different forms and should not be construed as limited to the exemplary embodiments set forth herein. Rather, these exemplary embodiments are provided so that this disclosure will be thorough and complete and will convey the scope of this disclosure to those skilled in the art. In the description, details of well-known features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements. As used herein, the term “same” when used for comparing values of a measurement, characteristic, parameter, etc., such as “the same width,” means nominally identical, such as within industry accepted tolerances for the measurement, characteristic, parameter, etc., unless the context indicates a different meaning. As used herein, the terms “about,” “approximately,” “significantly, or similar terms, when used to modify physical or temporal values, such as length, time, temperature, quantity, electrical characteristics, superconducting characteristics, etc., or when such values are stated without such modifiers, means nominally equal to the specified value in recognition of variations to the values that can occur during typical handling, processing, and measurement procedures. These terms are intended to include the degree of error associated with measurement of the physical or temporal value based upon the equipment available at the time of filing the application, or a value within accepted engineering tolerances of the stated value. For example, the term “about” or similar can include a range of ±8% or 5%, or 2% of a given value. In one aspect, the term “about” or similar means within 10% of the specified numerical value. In another aspect, the term “about” or similar means within 5% of the specified numerical value. Yet, in another aspect, the term “about” or similar means within 10, 9, 8, 7, 6, 5, 4, 3, 2, or 1% of the specified numerical value. In another aspect, these terms mean within industry accepted tolerances.

For the clarity of the description, and without implying any limitation thereto, illustrative embodiments may be described using simplified diagrams. In an actual fabrication, additional structures that are not shown or described herein, or structures different from those shown and described herein, may be present without departing from the scope of the illustrative embodiments.

Differently patterned portions in the drawings of the example structures, layers, and formations are intended to represent different structures, layers, materials, and formations in the example fabrication, as described herein. A specific shape, location, position, or dimension of a shape depicted herein is not intended to be limiting on the illustrative embodiments unless such a characteristic is expressly described as a feature of an embodiment. The shape, location, position, dimension, or some combination thereof, are chosen only for the clarity of the drawings and the description and may have been exaggerated, minimized, or otherwise changed from actual shape, location, position, or dimension that might be used in actual fabrication to achieve an objective according to the illustrative embodiments.

An embodiment when implemented in an application causes a fabrication process to perform certain steps as described herein. The steps of the fabrication process are depicted in the several figures. Unless such a characteristic is expressly described as a feature of an embodiment, not all steps may be necessary in a particular fabrication process; some fabrication processes may implement the steps in different order, combine certain steps, remove or replace certain steps, or perform some combination of these and other manipulations of steps, without departing the scope of the illustrative embodiments.

The illustrative embodiments are described with respect to certain types of materials, electrical properties, structures, formations, layers orientations, directions, steps, operations, planes, dimensions, numerosity, data processing systems, environments, and components. Unless such a characteristic is expressly described as a feature of an embodiment, any specific descriptions of these and other similar artifacts are not intended to be limiting to the invention; any suitable manifestation of these and other similar artifacts can be selected within the scope of the illustrative embodiments.

The illustrative embodiments are described using specific designs, architectures, layouts, schematics, and tools only as examples and are not limiting to the illustrative embodiments. The illustrative embodiments may be used in conjunction with other comparable or similarly purposed designs, architectures, layouts, schematics, and tools.

For the sake of brevity, conventional techniques related to microelectronic fabrication may or may not be described in detail herein. Moreover, the various tasks and process steps described herein can be incorporated into a more comprehensive procedure or process having additional steps or functionality not described in detail herein. In particular, various steps in the manufacture of microelectronic devices may be well known and so, in the interest of brevity, many conventional steps may only be mentioned briefly or may be omitted entirely without providing the well-known process details.

In the following descriptions, the term length applies to dimensional characteristics along the x-axis.

In the following descriptions, the term width applies to dimensional characteristics along the y-axis.

In the following descriptions, the term thickness applies to dimensional characteristics along the z-axis.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Various processes used to form a micro-chip that will be packaged into an integrated circuit (IC) fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

Reference will now be made in detail to the embodiments of the present invention, examples of which are illustrated in the accompanying drawings, wherein like reference numerals refer to like elements throughout.

Coaxial attenuators require large areas per connector and will severely limit the channel count that can be housed in the cryostat. Attenuators using thin resistive metal foils can be integrated into FLEX ribbons and solve the channel density problem. However, ensuring that then attenuators are thermalized to the temperature bulkhead is difficult due to the dielectrics (that are thermally insulating) that surround the resistive elements of the attenuators. The heat generated by the resistor in a typical attenuator cannot easily traverse the surround dielectric material to reach the thermal reservoir.

The present invention divides the resistor of the attenuator in half and inserts a thermal shunt located about the middle of the resistor. By splitting/perforating the resistor and placing thermal shunt in the middle of the resistor, then the generated heat from the resistor can be shunted into the thermal reservoir, while avoiding the thermal resistance of the dielectric layers.

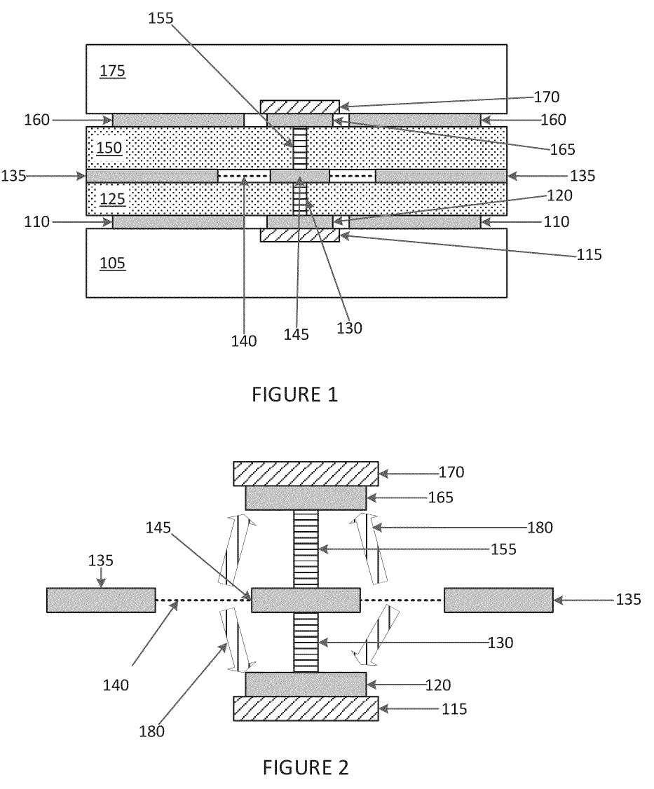

FIG. 1 represents a cross sectional view depicting an attenuator, according to an example embodiment. The attenuator includes a first thermal reservoir 105, a first metal plate 110, a second metal plate 120, a first thermal material 120, a first dielectric layer 125, a third metal plate 135, a resistor 140, a second dielectric layer 150, a fourth metal plate 160, a sixth metal plate 165, a second thermal material 170, and a second thermal reservoir 175. The metal plates 110, 120, 135, 160, and 165 can be comprised of, for example, an electrical conducting metal such as Cu. The heat generated by the resistor 140 cannot easily traverse the surround first and second dielectric layers 125 and 150 to reach the first or second thermal reservoir 105, 170. A dividing metal plate 145 splits the resistor 140 in half. The dividing metal plate 145 can be comprised of, for example, Cu. A first thermal via 130 extends downwards from the dividing metal plate 145 to the second metal plate 120. A second thermal via 155 extends upwards from the dividing metal plate 145 to the sixth metal plate 165. The first thermal via 130 and the second thermal via 155 can be lined with Cu. By splitting/perforating the resistor 140 and placing thermal shunt (i.e., the dividing metal plate 145, the first thermal via 130 and the second thermal via 155) in the middle of the resistor 140, then the generated heat from the resistor 140 can be shunted into the first and second thermal reservoir 105 and 175, while avoid the thermal resistance of the first and second dielectric layers 125 and 150. The first thermal layer 120 and the second thermal layer 170 electrical insulate the second metal plate 130 and the sixth metal plate 165 from the first and second thermal reservoir 105 and 175, respectively.

FIG. 2 represents a cross sectional view of a split resistor with the thermal vias, according to an example embodiment. FIG. 2 illustrates a closer view of the split resistor 140. Arrows 180 illustrate the flow of heat from the resistor 140 via the first thermal via 130 and the second thermal via 155 to the second metal plate 120 and the sixth metal plate 165, respectively.

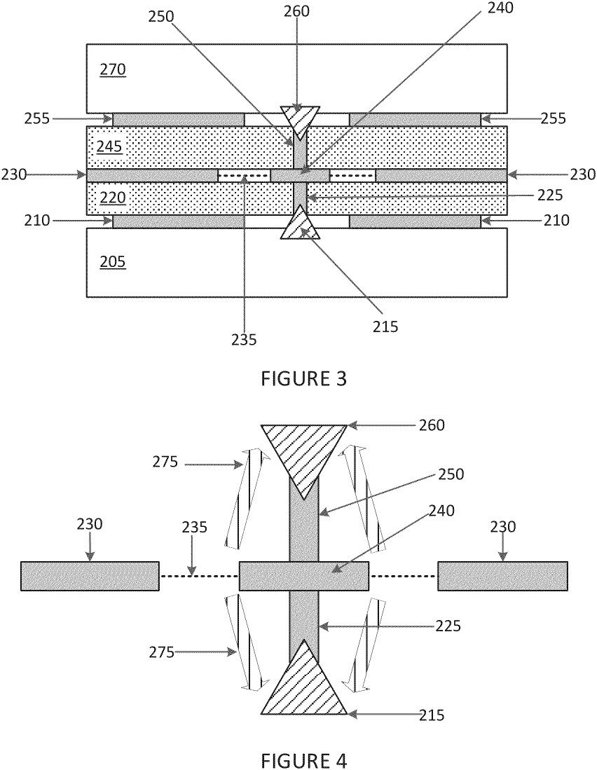

FIG. 3 represents a cross sectional view depicting an attenuator, according to an example embodiment. The attenuator includes a first thermal reservoir 205, a first metal plate 210, a first thermal material 215, a first dielectric layer 220, a third metal plate 230, a resistor 235, a second dielectric layer 245, a fourth metal plate 255, a second thermal material 260, and a second thermal reservoir 270. The heat generated by the resistor 235 cannot easily traverse the surround first and second dielectric layers 220 and 245 to reach the first or second thermal reservoir 205, 270. A dividing metal plate 240 splits the resistor 235 in half. The dividing metal plate 240 can be comprised of, for example, Cu. A first thermal via 225 extends downwards from the dividing metal plate 240 to the first thermal layer 215. A second thermal via 250 extends upwards from the dividing metal plate 240 to the second thermal layer 260. The first thermal via 225 and the second thermal via 250 can be lined with Cu. This configuration eliminates capacitance of surface pads, but not as thermally conductive as the exampled illustrated by FIGS. 1 and 2, but electrically better performance.

FIG. 4 represents a cross sectional view of a split resistor with the thermal vias, according to an example embodiment. FIG. 4 illustrates a closer view of the split resistor 235. Arrows 275 illustrate the flow of heat from the resistor 235 via the first thermal via 225 and the second thermal via 250 to the first thermal layer 215 and the second thermal layer 260, respectively.

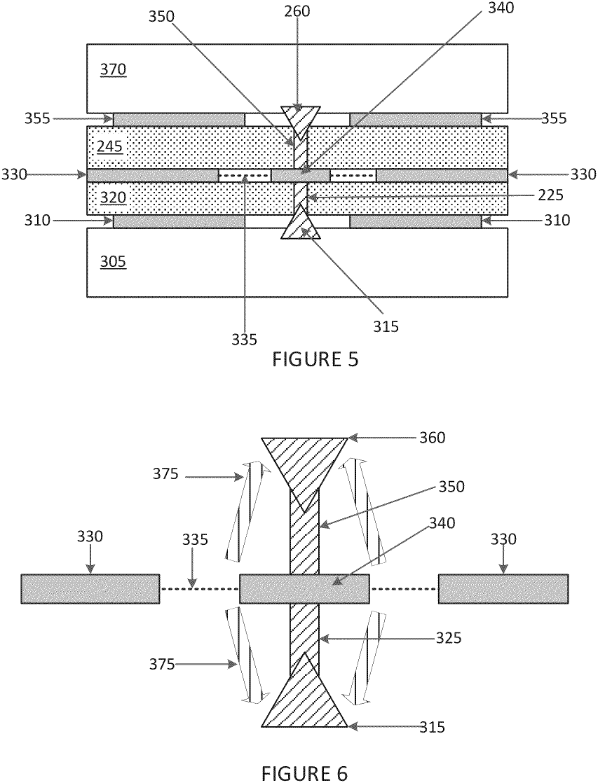

FIG. 5 represents a cross sectional view depicting an attenuator, according to an example embodiment. The attenuator includes a first thermal reservoir 305, a first metal plate 310, a first thermal material 315, a first dielectric layer 320, a third metal plate 330, a resistor 335, a second dielectric layer 345, a fourth metal plate 355, a second thermal material 360, and a second thermal reservoir 370. The heat generated by the resistor 335 cannot easily traverse the surround first and second dielectric layers 320 and 345 to reach the first or second thermal reservoir 305, 370. A dividing metal plate 340 splits the resistor 335 in half. The dividing metal plate 340 can be comprised of, for example, Cu. A first thermal via 325 extends downwards from the dividing metal plate 340 to the first thermal layer 315. A second thermal via 350 extends upwards from the dividing metal plate 340 to the second thermal layer 360. The first thermal via 325 and the second thermal via 350 can be filled with a thermal interface material. This configuration eliminates capacitance of surface pads, but not as thermally conductive as the exampled illustrated by FIGS. 1 and 2, but electrically better performance. Furthermore, this configuration eliminates capacitance of via barrel as well, but not as thermally conductive as illustrated by FIGS. 1-4, but electrically better performance than other two.

FIG. 6 represents a cross sectional view of a split resistor with the thermal vias, according to an example embodiment. FIG. 6 illustrates a closer view of the split resistor 335. Arrows 375 illustrate the flow of heat from the resistor 335 via the first thermal via 325 and the second thermal via 350 to the first thermal layer 315 and the second thermal layer 360, respectively.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. An attenuator comprising:
a first thermal reservoir;
a first metal layer located on top of the first thermal reservoir;
a first dielectric layer located on top of the first metal layer;
a resistor located on top the first dielectric layer;
a second dielectric layer located on top of the resistor;
a second metal layer located on top of the second dielectric layer;
a second thermal reservoir located on top the third metal layer;
wherein the resistor is split or perforated by a thermal shunt, wherein the thermal shunt includes a thermal column that directs the heat generated by the resistor vertically upwards or downwards into the first and second thermal reservoirs, respectively.

2. The attenuator of claim 1, further comprising:
a dividing metal plate that splits the resistor.

3. The attenuator of claim 2, further comprising:
a top thermal via that extends upwards from the dividing metal plate through the second dielectric layer to the second thermal reservoir.

4. The attenuator of claim 3, further comprising:
a bottom thermal via that extends downwards from the dividing metal plate through the first dielectric layer to the first thermal reservoir.

7. The attenuator of claim 4, wherein the top thermal via and the bottom thermal via are lined with Cu.

8. The attenuator of claim 7, wherein the bottom thermal via is in direct contact with a first thermal interface material layer, such that the heat generated by the resistor is shunted downwards though the bottom thermal via to the first thermal interface material layer and to the first thermal reservoir.

9. The attenuator of claim 8, further comprising:
a bottom metal plate located between the bottom of the bottom thermal via and the first thermal interface material layer.

10. The attenuator of claim 8, wherein the top thermal via is in direct contact with a second thermal interface material layer, such that the heat generated by the resistor is shunted upwards though the top thermal via to the second thermal interface material layer and to the second thermal reservoir.

11. The attenuator of claim 10, further comprising:
a top metal plate located between the top of the top thermal via and the second thermal interface material layer.

12. An attenuator comprising:
a first thermal reservoir;
a first metal layer located on top of the first thermal reservoir;
a first dielectric layer located on top of the first metal layer;
a resistor located on top the first dielectric layer;
a second dielectric layer located on top of the resistor;
a second metal layer located on top of the second dielectric layer;
a second thermal reservoir located on top the third metal layer;
a top thermal via that extends upwards from resistor through the second dielectric layer to the second thermal reservoir, wherein the top thermal via is filled with a thermal interface material; and
a bottom thermal via that extends downwards from the dividing metal plate through the first dielectric layer to the first thermal reservoir, wherein the bottom thermal via is filled with a thermal interface material.

13. The attenuator of claim 12, further comprising:
a dividing metal plate that splits the resistor.

14. The attenuator of claim 13, wherein the top thermal via that extends upwards from the dividing metal plate through the second dielectric layer to the second thermal reservoir.

15. The attenuator of claim 14, wherein the bottom thermal via that extends downwards from the dividing metal plate through the first dielectric layer to the first thermal reservoir.

16. The attenuator of claim 15, wherein the bottom thermal via is in direct contact with a first thermal interface material layer, such that the heat generated by the resistor is shunted downwards though the bottom thermal via to the first thermal interface material layer and to the first thermal reservoir.

17. The attenuator of claim 16, wherein the top thermal via is in direct contact with a second thermal interface material layer, such that the heat generated by the resistor is shunted upwards though the top thermal via to the second thermal interface material layer and to the second thermal reservoir.
